(19) United States
(12) Patent Application Publication
(10) Pub. No.: US 2026/0353929 A1
(43) Pub. Date: Nov. 5, 2026

(54) Display Device

(71) Applicant: LG Display Co., Ltd., Seoul (KR)

(72) Inventors: Heechul Lim, Paju-si (KR); Hyein Park, Gwangju (KR)

(21) Appl. No.: 19/548,846

(22) Filed: Feb. 24, 2026

(30) Foreign Application Priority Data
Apr. 30, 2025 (KR) 10-2025-0056907

(51) Int. Cl. H10K 59/122; H10K 59/124

(52) U.S. Cl. CPC H10K 59/122; H10K 59/124

(57) ABSTRACT

A display device according to an exemplary embodiment of the present disclosure may include a substrate including a display area and a non-display area, a planarization layer disposed over the substrate and extending from the display area to the non-display area, an anode disposed on the planarization layer, a bank disposed on the planarization layer and configured to expose a part of the anode corresponding to an emission area, an organic layer disposed in the emission area, a cathode disposed on the organic layer and extending to the non-display area, a protective layer disposed on the cathode, and an oxygen getter disposed in the planarization layer under the bank, thereby enhancing the reliability of the display device and improving durability of the light emitting element.

### CROSS-REFERENCE TO RELATED APPLICATIONS

This application claims the priority of Republic of Korea Patent Application No. 10-2025-0056907 filed on Apr. 30, 2025, in the Ministry of Intellectual Property of the Republic of Korea, the disclosure of which is incorporated herein by reference.

### FIELD

The present disclosure relates to a display device, and more particularly, to a display device in which penetration of moisture and oxygen is minimized.

### BACKGROUND

Currently, as the world enters a full-fledged information era, the field of display devices that visually display electrical information signals is rapidly developing, and research is being conducted to develop performances characteristics such as thinning, weight reduction, and low power consumption for various display devices.

Representative display devices include a liquid crystal display (LCD), an electro-wetting display (EWD), and an organic light emitting display (OLED).

Among these, an electroluminescent display device including an organic light emitting display device is a self-emitting display device and does not require a separate light source unlike a liquid crystal display device, and thus may be manufactured to have a light weight and a small thickness. In addition, the electroluminescent display device is advantageous not only in terms of power consumption due to low voltage driving, but also in terms of color reproduction, response speed, viewing angle, and contrast ratio, so that it is expected to be used in various fields.

In the organic light emitting display device, since the organic layer constituting the light emitting element is vulnerable to heat, moisture, oxygen, and the like, it is important to develop a display device capable of minimizing the penetration of moisture and oxygen.

### SUMMARY

An object of the present disclosure is to provide a display device capable of minimizing penetration of moisture and oxygen.

Another object to be achieved by the present disclosure is to provide a display device capable of preventing a dark spot defect by effectively collecting oxygen introduced through a damaged cathode.

Still another object to be achieved by the present disclosure is to provide a display device which can be simply applied without making a significant change in an existing manufacturing process while preventing the penetration of moisture and oxygen.

Objects of the present disclosure are not limited to the above-mentioned objects, and other objects, which are not mentioned above, can be clearly understood by those skilled in the art from the following descriptions.

A display device according to an exemplary embodiment of the present disclosure may include a substrate including a display area and a non-display area, a planarization layer disposed over the substrate and extending from the display area to the non-display area, an anode disposed on the planarization layer, a bank disposed on the planarization layer and exposing a part of the anode corresponding to an emission area, and extending to the non-display area, an organic layer disposed in the emission area, a cathode disposed on the organic layer and extending to the non-display area, a protective layer disposed on the cathode, and an oxygen getter disposed in the planarization layer under the bank.

Other detailed matters of the embodiments are included in the detailed description and the drawings.

According to the present disclosure, the penetration of moisture and oxygen may be minimized by forming a trench pattern at the edge of the non-display area. Accordingly, it is possible to increase the reliability of the display device and improve the durability of the light emitting element.

According to the present disclosure, an oxygen getter is added to an insulating layer under a black bank or a top surface or inside the black bank to effectively collect oxygen introduced through the damaged cathode, thereby preventing a dark spot defect. Accordingly, the reliability and yield of the display device are improved, and stable performance may be maintained even during long-term use. Further, the display device can stably operate even in extreme environments such as high temperature, high humidity, and low temperature, and can prevent performance deterioration even in various environments.

The present disclosure may be applied without significant changes to an existing manufacturing process, thereby providing an effect of improving productivity and reducing manufacturing costs.

In the present disclosure, due to the increase in yield, resource consumption in the manufacturing process may be reduced, and accordingly, the use of fossil fuels may be reduced. As a result, greenhouse gas emissions are reduced, thereby contributing to the implementation of ESG (Environment/Social/Governance) targets. This contributes to building a sustainable manufacturing environment and provides positive environmental aspects.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a display device according to a first embodiment of the present disclosure.

FIG. 2 is a cross-sectional view taken along line A-A' in FIG. 1.

FIG. 3 is a cross-sectional view of a display device according to a second embodiment of the present disclosure.

FIG. 4 is a cross-sectional view of a display device according to a third embodiment of the present disclosure.

FIG. 5 is a plan view of a display device according to a fourth embodiment of the present disclosure.

FIG. 6 is a cross-sectional view taken along line B-B' in FIG. 5.

FIG. 7 is a cross-sectional view of a display device according to a fifth embodiment of the present disclosure.

FIG. 8 is a cross-sectional view of a display device according to a sixth embodiment of the present disclosure.

FIG. 9 is a plan view of a display device according to a seventh embodiment of the present disclosure.

FIG. 10 is a cross-sectional view taken along line C-C' in FIG. 9.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the accompanying drawings.

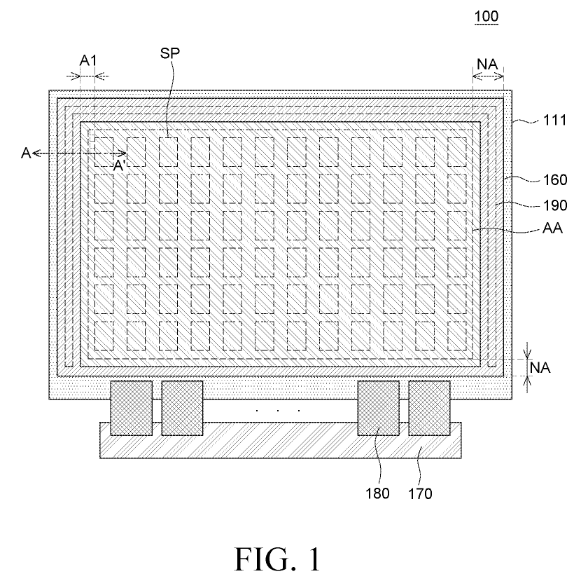

FIG. 1 is a plan view of a display device according to a first embodiment of the present disclosure.

Referring to FIG. 1, a display device 100 according to a first embodiment of the present disclosure may include a display panel, a flexible film 180, and a printed circuit board 170.

The display panel is a panel for displaying images to a user.

The display panel may be simply configured by an encapsulation part including the substrate 111, a sealing member on the substrate 111, and the encapsulation substrate 160.

In the display panel, a display element for displaying an image, a driving element for driving the display element, and lines for transmitting various signals to the display element and the driving element may be disposed. The display element may be defined in different ways depending on the type of the display panel. For example, when the display panel is an organic light emitting display panel, the display element may be an organic light emitting element including an anode, an organic emission layer, and a cathode. For example, when the display panel is a liquid crystal display panel, the display element may be a liquid crystal display element.

Hereinafter, even though it is assumed that the display panel is an organic light emitting display panel, the display panel is not limited to the organic light emitting display panel.

The display panel may include a display area AA and a non-display area NA.

The display area AA is an area in which images are displayed in the display panel.

In the display area AA, a plurality of sub pixels SP constituting a plurality of pixels and a circuit for driving the plurality of sub pixels SP may be disposed. The plurality of sub pixels SP is a minimum unit constituting the display area AA, and a display element may be disposed in each of the plurality of sub pixels SP, and the plurality of sub pixels SP may constitute a pixel. For example, an organic light emitting element including an anode, an organic emission layer, and a cathode may be disposed in each of the plurality of sub pixels SP, but is not limited thereto. Further, a circuit for driving the plurality of sub pixels SP may include a driving element, a line, and the like. For example, the circuit may include a thin film transistor, a storage capacitor, a gate line, a data line, and the like, but is not limited thereto.

The non-display area NA is an area where no image is displayed.

FIG. 1 illustrates that the non-display area NA encloses the display area AA having a rectangular shape. However, the shapes and arrangements of the display area AA and the non-display area NA are not limited to the example illustrated in FIG. 1.

The display area AA and the non-display area NA may have shapes suitable for a design of an electronic device including the display device. For example, the display area AA may have various shapes such as a pentagon, a hexagon, a circle, and an oval.

In the non-display area NA, various lines and circuits for driving the organic light emitting element of the display area AA may be disposed. For example, in the non-display area NA, link lines for transmitting signals to the plurality of sub pixels SP and the circuit in the display area AA or driving ICs such as a gate driver IC and a data driver IC may be disposed, but are not limited thereto.

The display device 100 may include various additional elements for generating various signals or driving pixels in the display area AA. The additional elements for driving the pixels may include an inverter circuit, a multiplexer, an electrostatic discharge (ESD) circuit, and the like. The display device 100 may also include additional elements related to functions other than pixel driving. For example, the display device 100 may include additional elements that provide a touch sensing function, a user authentication function (e.g., fingerprint recognition), a multi-level pressure sensing function, a tactile feedback function, and the like. The above-mentioned additional elements may be located in the non-display area NA and/or in an external circuit connected to a connection interface.

The flexible film 180 is a film in which various components are disposed on a base film having flexibility. For example, the flexible film 180 is a film for supplying signals to the plurality of sub pixels SP and the circuit in the display area AA and may be electrically connected to the display panel. The flexible film 180 is disposed at one end of the non-display area NA of the display panel to supply a power voltage and a data voltage to the plurality of sub pixels SP and the circuit of the display area AA. The number of flexible films 180 may be varied according to design, but is not limited thereto.

Meanwhile, for example, a driving IC such as a gate driver IC and a data driver IC may be disposed on the flexible film 180. The driving IC is a component that processes data for displaying an image and a driving signal for processing the data. The driving IC may be disposed by a chip on glass (COG), a chip on film (COF), or a tape carrier package (TCP) method, or the like depending on a mounting method.

The printed circuit board 170 may be disposed at one end of the flexible film 180 and connected to the flexible film 180. The printed circuit board 170 is a component that supplies signals to the driving IC. The printed circuit board 170 may supply various signals such as a driving signal and a data signal to the driving IC. For example, a data driver for generating data signals may be mounted on the printed circuit board 170, and the generated data signal may be supplied to the plurality of sub pixels SP and the circuit of the display panel through the flexible film 180. The number of printed circuit boards 170 may vary depending on the design, but is not limited thereto.

In the first embodiment of the present disclosure, the trench pattern 190 formed by removing a part of the planarization layer may be disposed in the non-display area NA, and a cathode may be partially extended onto the trench pattern 190. Accordingly, in the first embodiment of the present disclosure, the rate at which moisture and oxygen penetrate into a side surface of the display panel may be delayed. Accordingly, it is possible to increase the reliability of the display device 100 and improve the durability of the light emitting element.

The trench pattern 190 may be disposed in a frame shape along three sides of the non-display area NA excluding one side of the display panel. That is, with reference to FIG. 1, a lower side of the display panel is not suitable for forming the trench pattern 190 due to the arrangement of the driving IC and the connection of the flexible film 180. Therefore, the trench pattern 190 may be disposed over the edges of the three sides of the display panel excluding the lower side. However, the present disclosure is not limited thereto, and for example, the trench pattern 190 may be disposed in a rectangular frame shape along all four sides of the non-display area NA of the display panel.

As described above, the encapsulation part may include an adhesive layer and an encapsulation substrate 160.

According to the present disclosure, for example, an encapsulation structure of a multilayer structure including a relatively thick encapsulation substrate 160 may be applied. In this case, rigidity and a heat dissipation effect may be sufficiently secured. However, the present disclosure is not limited thereto.

Meanwhile, in the first embodiment of the present disclosure, an oxygen getter is added to an insulating layer under a black bank to collect oxygen introduced through a damaged cathode, thereby preventing a dark spot defect. FIG. 1 illustrates a first area A1 of a planarization layer including an oxygen getter as an example, and the first area A1 may be set in a mesh shape in a space excluding the sub pixel SP in a display area AA in which the sub pixel SP is disposed in a matrix, and a part of the non-display area NA inside the trench pattern 190. However, the present disclosure is not limited thereto.

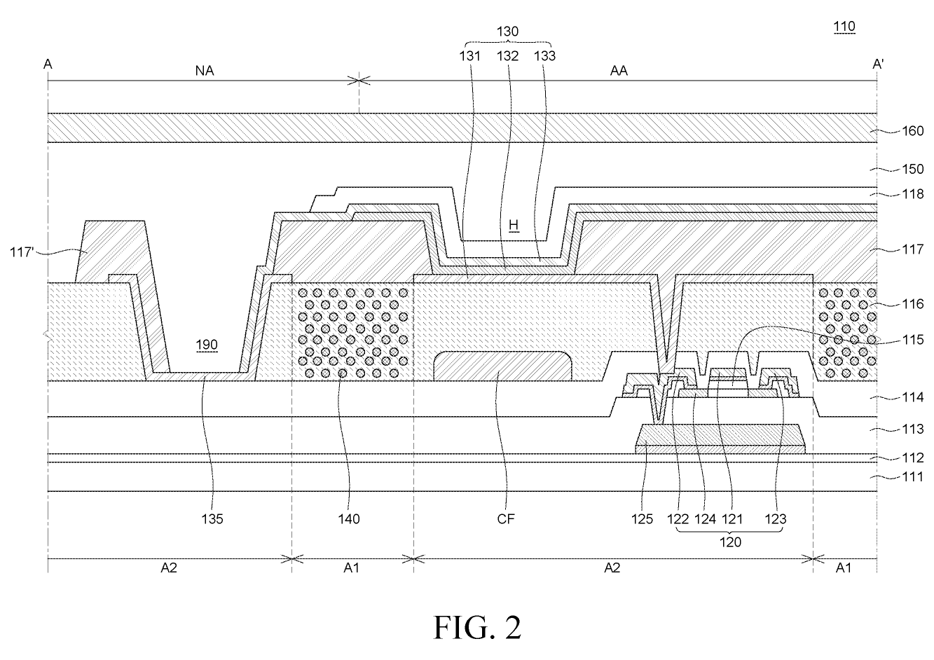

Hereinafter, the first area A1 of the planarization layer including the trench pattern 190 and the oxygen getter according to the first embodiment will be described in detail with reference to FIG. 2.

FIG. 2 is a cross-sectional view taken along line A-A' in FIG. 1.

FIG. 2 exemplarily illustrates a cross-section of a part of the left side of the display panel 110 on which the trench pattern 190 is formed.

Referring to FIG. 2, in the display panel 110 according to the first embodiment of the present disclosure, the driving element 120 may be disposed on the substrate 111.

Further, the planarization layer 116 may be disposed on the driving element 120.

Further, the light emitting element 130 electrically connected to the driving element 120 may be disposed on the planarization layer 116 and the protective layer 118 may be disposed on the light emitting element 130 to minimize the penetration of oxygen and moisture into the light emitting element 130.

The adhesive layer 150 and the encapsulation substrate 160 may be sequentially disposed on the protective layer 118. However, the display panel 110 according to the first embodiment of the present disclosure is not limited to such a laminated structure.

The adhesive layer 150 may be referred to as a sealing member, and the encapsulation substrate 160 may be referred to as a reinforcing substrate.

The substrate 111 may be a glass or plastic substrate.

When the substrate 111 is a plastic substrate, for example, a polyimide-based or polycarbonate-based material may be used to have flexibility.

Polyimide is widely used as a plastic substrate because it can be applied to a high-temperature process and is a material capable of coating.

A buffer layer 112 may be disposed on the substrate .111

The buffer layer 112 is a functional layer for protecting various electrodes and lines from impurities such as alkali ions flowing out of the substrate 111 or the underlying layers. The buffer layer 112 may have a multilayer structure including a first buffer layer and a second buffer layer, but is not limited thereto. For example, the buffer layer 112 may be made of silicon oxide (SiOx), silicon nitride (SiNx), or a multi-layer thereof.

The buffer layer 112 may delay diffusion of moisture and/or oxygen permeating the substrate 111. In addition, the buffer layer 112 may include a multi-buffer layer and/or an active buffer layer.

For example, the buffer layer 112 may extend to the end of the substrate 111 in the non-display area NA, but is not limited thereto.

The light shielding layer 125 may be disposed on the buffer layer 112. The light shielding layer 125 may be formed for the purpose of preventing external light from flowing into the active layer 124 of the driving element 120 disposed thereon.

When the light shielding layer 125 is disposed on the buffer layer 112, the active buffer layer 113 may be disposed on the light shielding layer 125. The active buffer layer 113 protects the active layer 124 made of the semiconductor of the driving element 120 and may block various types of defects introduced from the substrate 111.

The driving element 120 may be disposed on the active buffer layer 113.

For example, the driving element 120 may have a form in which the active layer 124, the gate insulating layer 115, the gate electrode 121, the source electrode 123, and the drain electrode 122 are sequentially disposed, and may be electrically connected to the light emitting element 130 to transmit a current or a signal to the light emitting element 130.

The active layer 124 may be disposed on the active buffer layer 113.

The active layer 124 may be made of polysilicon (p-Si), and in this case, a predetermined area may be doped with impurities. Further, the active layer 124 may be made of amorphous silicon (a-Si) and may be made of various organic semiconductor materials such as pentacene. Furthermore, the active layer 124 may be formed of oxide.

The gate insulating layer 115 may be disposed on the active layer 124.

The gate insulating layer 115 may be formed of an insulating inorganic material such as silicon oxide (SiOx) or silicon nitride (SiNx), or an insulating organic material. The gate insulating layer 115 may be disposed on the gate electrode 121 and the active layer 124 under the source electrode 123 and the drain electrode 122 in an island shape, but is not limited thereto and may be disposed on the entire surface of the substrate 111.

The gate electrode 121, the source electrode 123, and the drain electrode 122 may be disposed on the gate insulating layer 115, but are not limited thereto. The gate electrode 121, the source electrode 123, and the drain electrode 122 may be disposed on different layers through the interlayer insulating layer.

The gate electrode 121, the source electrode 123, and the drain electrode 122 may be formed of various conductive materials, such as magnesium (Mg), aluminum (Al), nickel (Ni), chromium (Cr), molybdenum (Mo), tungsten (W), gold (Au), or an alloy thereof.

A contact hole through which the source area and the drain area of the active layer 124 are exposed may be formed by selective removal of the gate insulating layer 115.

A source area and a drain area of the active layer 124 may be electrically connected to the source electrode 123 and the drain electrode 122, respectively, through the contact hole.

A part of the drain electrode 122 may be electrically connected to the light shielding layer 125 through another contact hole from which the active buffer layer 113 is removed, but is not limited thereto.

An interlayer insulating layer 114 made of an inorganic insulating material may be disposed on the gate electrode 121, the source electrode 123, and the drain electrode 122 so as to cover the gate electrode 121, the source electrode 123, and the drain electrode 122.

Meanwhile, a color filter CF may be disposed on the interlayer insulating layer 114, but is not limited thereto, and the color filter CF may be omitted depending on the type of the light emitting element 130.

The color filter CF of each sub pixel may have any one of red, green, and blue colors. In addition, in the case of a sub pixel in which white is implemented, the color filter CF may not be disposed. The arrangement of red, green and blue may be formed in various ways.

In the case of the bottom emission type, the color filter CF may be located under the anode 131.

The planarization layer 116 may be disposed on the driving element 120 configured as described above.

The planarization layer 116 may have a multilayer structure including at least two layers.

For example, the planarization layer 116 may extend to the end of the substrate 111 in the non-display area NA, but is not limited thereto and may be disposed to be spaced apart from the end of the substrate 111 by a predetermined distance.

The planarization layer 116 may have a thickness of about 2 μm, but is not limited thereto.

The planarization layer 116 may be an overcoat layer, but is not limited thereto.

The reason why the planarization layer 116 is composed of two layers is that the number of signal lines increases as the resolution of the display panel increases. As a result, it is difficult to arrange all lines on one layer at minimum intervals, and an additional layer is formed. Through this additional layer, there is room for line arrangement, and it is easy to design line and electrode arrangement. In addition, when a dielectric material is used for the planarization layer 116, it may also be used to form capacitance between metal layers.

The planarization layer 116 and the interlayer insulating layer 114 may be formed to expose a part of the drain electrode 122, and the drain electrode 122 of the driving element 120 and the anode 131 of the light emitting element 130 may be electrically connected through another contact hole.

The light emitting element 130 may be disposed on the planarization layer 116. The light emitting element 130 may be configured such that the anode 131, a plurality of organic layers 132, and the cathode 133 are sequentially disposed. The light emitting element 130 may include an anode 131 disposed on the planarization layer 116, an organic layer 132 disposed on the anode 131, and a cathode 133 disposed on the organic layer 132.

The display device may be implemented in a top emission type or a bottom emission type. In the top emission type, a reflective layer made of an opaque conductive material having a high reflectance, for example, silver (Ag), aluminum (Al), gold (Au), molybdenum (Mo), tungsten (W), chromium (Cr), or an alloy thereof may be added under the anode 131 so that light emitted from the organic layer 132 is reflected by the anode 131 and directed upward, for example, in the direction of the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display panel 110 of the present disclosure is a bottom emission type.

The bank 117 may be disposed in the remaining area excluding the emission area on the planarization layer 116. That is, the bank 117 may have a bank hole H exposing the anode 131 corresponding to the emission area.

The bank 117, according to the first embodiment of the present disclosure, may be formed of a black-based resin and may serve to improve reflective visibility. For example, the bank 117 may be configured by dispersing a black dye in an organic material, but is not limited thereto and may be formed of any black material as long as it has a black color. Further, for example, the organic material may be a cardo-based polymer or a polymer including epoxy acrylate, but is not limited thereto.

As described above, as the bank 117 includes a black material, the bank 117 may reduce external light reflection, particularly diffuse reflection, which may occur when the bank 117 is made of a transparent material.

Further, the bank 117 may be formed of a plurality of layers. For example, the lower bank layer may be formed of a black material, but the upper bank layer disposed thereon may be formed of a transparent material. Further, the upper bank layer may include a spacer.

The bank 117 may have a thickness of about 1 μm, but is not limited thereto.

The organic layer 132 may be disposed on the anode 131 exposed by the bank 117. The organic layer 132 may include an emission layer, an electron injection layer, an electron transport layer, a hole transport layer, a hole injection layer, and the like.

For example, the organic layer 132 may be disposed on the bank 117 by including the bank hole H of the bank 117, but is not limited thereto, and some organic layers 132 may be disposed only on the anode 131.

The organic layer 132 may extend to the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

The cathode 133 may extend to the non-display area NA.

The cathode 133 may partially extend into the trench pattern 190 to be spaced apart from the end of the planarization layer 116 in the non-display area NA by a predetermined distance, but is not limited thereto.

Further, the cathode 133 may be disposed to cover a side surface of the organic layer 132 in the non-display area NA. The organic layer 132 may be disposed to be spaced apart from the end of the cathode 133 by a predetermined distance, but is not limited thereto.

A protective layer 118 may be disposed on the light emitting element 130. The protective layer 118 extends to the non-display area NA and may be disposed in the non-display area NA to be spaced apart from the end of the planarization layer 116 and the end of the cathode 133 by a predetermined distance. However, the present disclosure is not limited thereto.

A capping layer (not shown) made of a material having a high refractive index and a high light absorption rate may be disposed between the light emitting element 130 and the protective layer 118 to reduce diffused reflection of external light.

According to the first embodiment of the present disclosure, a portion of the planarization layer 116 is removed from the non-display area NA so that the trench pattern 190 may be disposed in the non-display area NA.

For example, the trench pattern 190 may be disposed in the non-display area NA positioned outside the display area AA.

Meanwhile, when viewed from the top, the trench pattern 190 may be disposed along the non-display area NA of the display panel 110. For example, the trench pattern 190 may be formed on an edge of the three sides of the display panel 110, and in this case, the trench pattern 190 may not be formed under the display panel 110 to which the flexible film is connected. However, the present disclosure is not limited thereto, and the trench pattern 190 may be formed on all four edges of the display panel 110.

For example, the trench pattern 190 may be formed by removing the planarization layer 116 of the non-display area NA positioned outside the display area AA through a photo process, but the present disclosure is not limited thereto.

FIG. 2 illustrates a case where one trench pattern 190 is provided as an example, but the present disclosure is not limited thereto. That is, the trench pattern 190 may be provided in a plurality of two or more and is not limited to the number of the trench patterns 190 illustrated in FIG. 2.

The trench pattern 190 may function to delay or partially block the penetration of moisture and oxygen introduced from the outside through the planarization layer 116 which is an organic film.

Meanwhile, the power line 135 may be disposed in the trench pattern 190. For example, the power line 135 may be a low potential power line for applying a negative voltage to the cathode 133, but the present disclosure is not limited thereto.

For example, the power line 135 may be disposed to cover the inside of the trench pattern 190. The power line 135 may be disposed to cover a side surface of the planarization layer 116 exposed by the trench pattern 190.

For example, the power line 135 may be disposed over the non-display area NA on the left, right, and upper sides of the display panel 110 along the trench pattern 190, but the present disclosure is not limited thereto.

For example, the cathode 133 may extend to the non-display area NA to cover an inner portion of the power line 135. In this case, the inner portion of the power line 135 is defined as a side portion adjacent to the display area AA, and may be a side portion facing the outer portion adjacent to the non-display area NA.

As described above, the power line 135 and the cathode 133 formed of a metal material in the trench pattern 190 are deposited to cover the side surface of the planarization layer 116 inside the trench pattern 190, thereby minimizing the penetration of moisture and oxygen.

Meanwhile, an outer structure 117’ having an island shape may be disposed outside the trench pattern 190 to cover an outer portion of the power line 135. In this case, the outer structure 117’ may be an outer bank made of an organic material constituting the bank 117. Accordingly, the bank 117 and the outer structure 117’ may be disposed to be separated from each other with respect to the trench pattern 190.

The outer structure 117’ may be disposed to be spaced apart from an edge of the adhesive layer 150 and the encapsulation substrate 160 by a predetermined distance. That is, in the first exemplary embodiment of the present disclosure, the outer structure 117’ is formed to cover the tapered portions of the power line 135 and the planarization layer 116 and removed from the remaining areas. Accordingly, the water transfer velocity (WTV) may be suppressed or reduced.

On the other hand, in the non-display area NA on the lower side where the trench pattern 190 is not formed, the bank 117 may not be separated into the outer structure 117’ and may extend to the non-display area NA along the planarization layer 116, but the present disclosure is not limited thereto.

Meanwhile, in the non-display area NA, the organic layer 132 may be disposed on the bank 117.

The organic layer 132 extends to the non-display area NA, and its edge may be disposed inside compared to the edge of the bank 117, but the present disclosure is not limited thereto.

In the non-display area NA, the cathode 133 may be disposed on the organic layer 132.

The cathode 133 may extend into the trench pattern 190 to cover the inner portion of the exposed power line 135, but the present disclosure is not limited thereto.

The cathode 133 may be in contact with the exposed top surface of the power line 135, and thus may receive low potential power from the power line 135.

Meanwhile, in the first embodiment of the present disclosure, the oxygen getter 140 is added to the planarization layer 116 under the black bank 117.

In general, when the cathode is deposited on the organic light emitting display panel and then exposed to moisture, a trace amount of moisture reacts with a reactor present on the surface of the black bank to form an acidic component. As a result, the cathode may be damaged, and in particular, when oxygen O2 penetrates into the panel through the damaged cathode, display defects such as dark spots may occur.

Accordingly, in the first embodiment of the present disclosure, in order to solve this problem, the oxygen getter 140 is added to the insulating layer under the black bank 117, for example, the planarization layer 116 under the bank 117. Accordingly, in the present disclosure, it is possible to effectively collect oxygen introduced into the inside due to the damage to the cathode 133, thereby reducing display defects and improving reliability.

As described above, in FIG. 1, the first area A1 of the planarization layer 116 including the oxygen getter 140 is illustrated as an example. When the sub pixels SP are disposed in a matrix form, the first area A1 may be set in a mesh form in a part of the display area AA corresponding to a boundary between the sub pixels SP and in a part of the non-display area NA located inside the trench pattern 190. However, the arrangement shape of the first area A1 is not limited to the mesh shape, and may be configured in various shapes.

Meanwhile, when the first area A1 is set to have a mesh shape, the oxygen getter 140 is uniformly distributed under the bank 117 to effectively cover a path in which oxygen is likely to be introduced, such as a gap between the cathode 133 and the bank 117. Accordingly, the oxygen getter 140 may quickly collect oxygen in the vicinity of the path through which oxygen penetrates, thereby efficiently blocking oxygen.

To this end, the planarization layer 116 may be divided into a first area A1 including an oxygen getter 140 and a second area A2 not including an oxygen getter 140. The first area A1 is mainly disposed below the bank 117, and the emission area in which the light emitting element 130 is formed and the circuit area in which a circuit such as the thin-film transistor TFT is disposed may deteriorate in electrical characteristics due to the presence of the oxygen getter 140. Therefore, the corresponding area may be set to the second area A2 in which the oxygen getter 140 is not included. That is, the first area A1 may be disposed under the bank 117 of the non-display area NA excluding the display area AA and the trench pattern 190 excluding the emission area and the circuit area, but the present disclosure is not limited thereto.

The oxygen getter 140 may include cerium dioxide (CeO2), barium-calcium (BaCa)-based metal oxide, a carbon molecular sieve or an alkaline earth metal such as barium (Ba), magnesium (Mg), strontium (Sr), and beryllium (Be). However, the present disclosure is not limited thereto.

Meanwhile, as described above, the protective layer 118 may be disposed on the light emitting element 130.

For example, the protective layer 118 may be made of an inorganic insulating material.

The protective layer 118 may delay moisture permeation from the top and suppress the occurrence of defects due to dents or foreign substances.

In order to delay moisture permeation, the protective layer 118 may be made of silicon oxide (SiOx), silicon nitride (SiNx), or a multilayer thereof, but is not limited thereto.

The adhesive layer 150 and the encapsulation substrate 160 may be disposed on the protective layer 118.

The adhesive layer 150 and the encapsulation substrate 160 may extend to the non-display area NA to cover a portion of the planarization layer 116, the trench pattern 190, and the protective layer 118.

The adhesive layer 150 may protect the light emitting element 130 from external moisture, oxygen, impact, and the like, together with the protective layer 118 and the encapsulation substrate 160.

The adhesive layer 150 may further include a moisture absorbent. The moisture absorbent may be particles having hygroscopicity and absorb moisture and oxygen to minimize the penetration of moisture and oxygen into the light emitting element 130.

The encapsulation substrate 160 may be disposed on the adhesive layer 150. The encapsulation substrate 160 may protect the light emitting element 130 together with the adhesive layer 150. The encapsulation substrate 160 may protect the light emitting element 130 from external moisture, oxygen, impact, and the like.

For example, the encapsulation substrate 160 may be formed of an iron/nickel alloy Invar, but is not limited thereto. The encapsulation structure of the present disclosure may be a multifilm structure including a thin film metal film, a barrier film such as aluminum foil, and a plurality of adhesive films and a reinforcing substrate such as an aluminum sheet.

As described above, the encapsulation structure of the multilayer structure composed of the adhesive layer 150 and the encapsulation substrate 160 may be disposed on the protective layer 118, but the present disclosure is not limited thereto. The encapsulation substrate 160 may be deleted.

For example, the adhesive layer 150 of the present disclosure may include a first adhesive layer facing the substrate 111, a second adhesive layer facing the encapsulation substrate 160, and a barrier layer disposed between the first adhesive layer and the second adhesive layer, but the present disclosure is not limited thereto.

Each of the first adhesive layer and the second adhesive layer may be made of a polymer material having adhesiveness.

For heat dissipation of the substrate 111, at least the first adhesive layer among the first and second adhesive layers may be formed of a mixture including particles of an adhesive polymer material and a metal material. Accordingly, since the speed at which the driving heat generated from the substrate 111 is discharged through the adhesive layer 150 may be improved, the heat dissipation effect on the substrate 111 may be improved.

Further, in order to prevent moisture permeation to the pixel unit, the first adhesive layer may be formed of a mixture further including a hygroscopic inorganic filler.

The second adhesive layer may not include the absorbent inorganic filler, and accordingly, the amount of use of the expensive absorbent inorganic filler may be reduced, thereby reducing the manufacturing cost of the adhesive layer 150. In addition, since the adhesiveness of the second adhesive layer may be improved than that of the first adhesive layer, the reliability of the bonding force of the substrate 111 and the encapsulation substrate 160 may be further improved.

As the first adhesive layer and the second adhesive layer are formed to have a multilayer structure, there is an advantage in that the reliability to reduce the warpage phenomenon in which the display panel is bent may also be improved.

The barrier layer may be formed of a metallic material.

The barrier layer may be introduced to be implemented as a stacked structure for reinforcing bonding with the first and second adhesive layers and reducing warpage.

Since the adhesive layer 150 according to the first embodiment of the present disclosure includes first and second adhesive layers separated by a barrier layer, it may be implemented to have a thickness approximately twice as thick as a single-layer adhesive material without a process defect. Therefore, since the encapsulation substrate 160 fixed by the adhesive layer 150 may be provided to have a larger thickness, it is possible to easily increase rigidity and improve the heat dissipation effect.

For example, the encapsulation substrate 160 may include any one of plastic polymers such as glass and PET.

Meanwhile, in the present disclosure, the protective layer may extend into the trench pattern so as to cover the cathode, which will be described in detail with reference to the drawings.

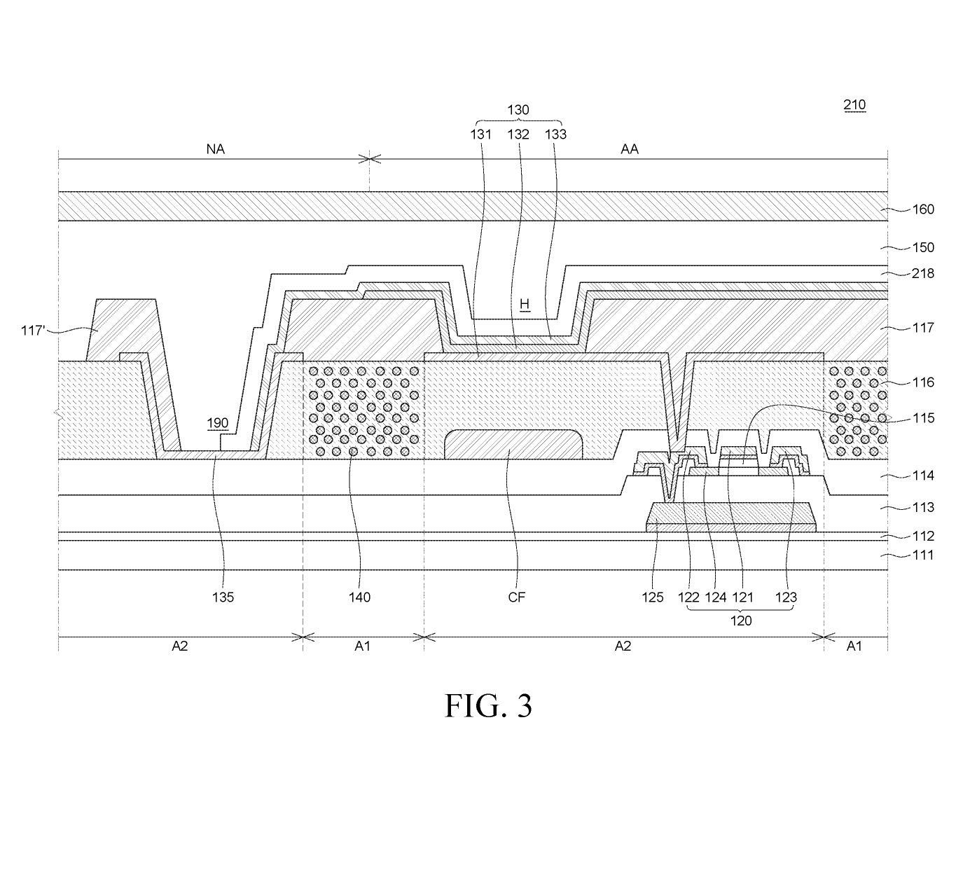

FIG. 3 is a cross-sectional view of a display device 210 according to a second embodiment of the present disclosure.

The second embodiment of the present disclosure of FIG. 3 differs from the first embodiment of FIGS. 1 and 2 described above in the configuration of the protective layer 218 and is substantially the same in other respects, and thus a redundant description will be omitted. In addition, the same reference numerals will be used for the same components, and descriptions of the same reference numerals and corresponding components may be made with reference to FIGS. 1 and 2.

Referring to FIG. 3, according to the second exemplary embodiment of the present disclosure, a part of the planarization layer 116 is removed from the non-display area NA so that the trench pattern 190 may be disposed.

In this case, the power line 135 may be disposed in the trench pattern 190.

For example, the power line 135 may be disposed to cover the inside of the trench pattern 190. The power line 135 may be disposed to cover a side surface of the planarization layer 116 exposed by the trench pattern 190.

Further, for example, the cathode 133 may extend to the non-display area NA to cover an inner portion of the power line 135.

Further, an outer structure 117’ having an island shape may be disposed outside the trench pattern 190 to cover an outer portion of the power line 135.

Further, in the non-display area NA, the organic layer 132 may be disposed on the bank 117.

In the non-display area NA, the cathode 133 may be disposed on the organic layer 132.

The cathode 133 may extend into the trench pattern 190 to cover the inner portion of the exposed power line 135, but the present disclosure is not limited thereto.

In the second exemplary embodiment of the present disclosure, the oxygen getter 140 may be added to the planarization layer 116 under the bank 117 in the same manner as in the first exemplary embodiment described above.

The oxygen getter 140 may be disposed in the first area A1 of the planarization layer 116.

For example, when the sub pixels SP are disposed in a matrix, the first area A1 may be set in a mesh form in a part of the display area AA corresponding to a boundary between the sub pixels SP and a part of the non-display area NA located inside the trench pattern 190.

A protective layer 218 may be disposed above the light emitting element 130.

For example, the protective layer 218 may be made of an inorganic insulating material.

Here, in the second embodiment of the present disclosure, the protective layer 218 may extend into the trench pattern 190 to cover the cathode 133, but the present disclosure is not limited thereto.

The protective layer 218 may cover the cathode 133 inside the trench pattern 190, thereby effectively blocking the penetration of moisture into the display device. When the protective layer 218 extends into the trench pattern 190, it is possible to minimize the penetration of moisture in the external environment into the display device, thereby further improving the durability and long-term stability of the display device.

As described above, in the second exemplary embodiment of the present disclosure, the protective layer 218 extends into the trench pattern 190 to cover the cathode 133, thereby effectively blocking external moisture penetration. Accordingly, the durability, performance, and reliability of the display device may be improved, and performance and reliability of the display device may also be improved.

In addition, the extension method of the protective layer may be modified in various forms, and the present disclosure is not limited thereto. Through the extension of the protective layer, it is possible to improve performance and reliability while extending the life of the display device. Accordingly, embodiments of the present disclosure may be appropriately adjusted according to a manufacturing process or a use environment to exhibit an optimal effect.

Meanwhile, according to the present disclosure, the cathode may be extended to the outer structure to cover the inside of the trench pattern, and the protective layer may be formed to cover the outer structure including the cathode, as will be described in detail with reference to the drawings.

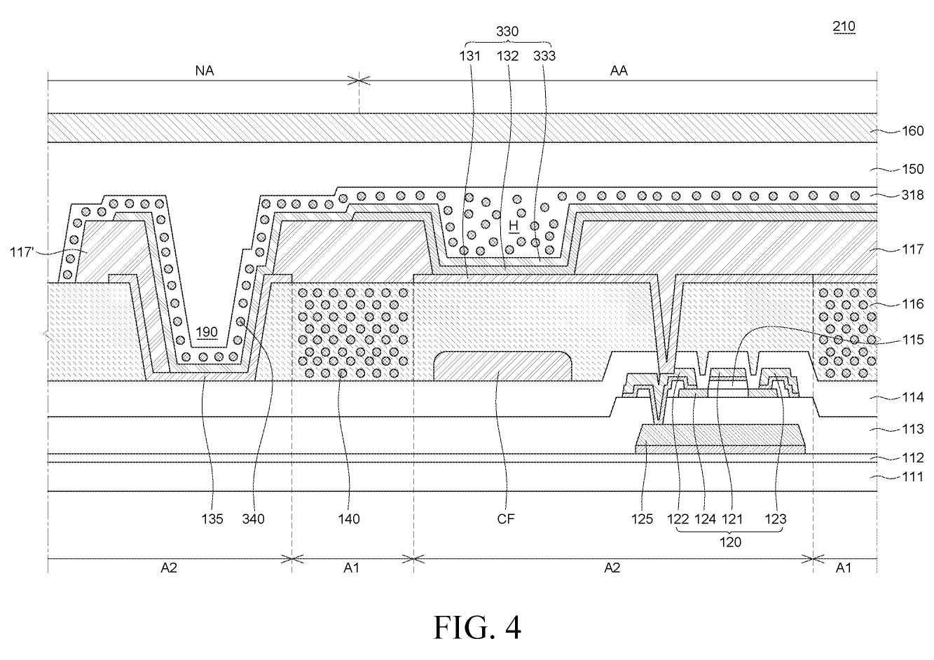

FIG. 4 is a cross-sectional view of a display device 310 according to a third embodiment of the present disclosure.

A configuration of the cathode 333 and the protective layer 318 of the light emitting element 330 differs from that of the first embodiment of FIGS. 1 and 2 described above, and other configurations are substantially the same, so that a redundant description will be omitted. The same reference numerals will be used for the same elements, and descriptions of the same reference numerals and corresponding elements may be made with reference to FIGS. 1-3.

Referring to FIG. 4, in the third embodiment of the present disclosure, the trench pattern 190 is formed in the non-display area NA, and the power line 135 may be disposed in the trench pattern 190. Further, an island-shaped outer structure 117′ may be disposed outside the trench pattern 190.

In the third embodiment of the present disclosure, the cathode 333 may cover the inner portion of the power line 135, and the power line 135 extending and exposed inside the trench pattern 190 may have its top surface covered by the cathode 333. In addition, the cathode 333 may extend to the outer structure 117′ located outside the trench pattern 190 so that the cathode 333 may cover not only the power line 135, but also a part of the inner region of the trench pattern 190 and the outer structure 117′, thereby effectively blocking the penetration of moisture from the external environment.

In addition, in the third embodiment of the present disclosure, the protective layer 318 may be disposed to cover the outer structure 117′ together with the cathode 333. The protective layer 318 may be formed of an inorganic insulating material and may completely cover the upper and side surfaces of the cathode 333 and the outer structure 117′ to more effectively block the penetration of moisture from the external environment. In particular, when the protective layer 318 is disposed to continuously cover the cathode 333 and the top surface of the outer structure 117’, the penetration of moisture into the display device may be more effectively blocked, thereby securing long-term reliability.

As described above, in the third exemplary embodiment of the present disclosure, the cathode 333 is disposed to extend to the outer structure 117′ including the inside of the trench pattern 190, and the protective layer 318 is disposed to cover the outer structure 117′ including the cathode 333 to maximize the durability and reliability of the display device.

As described above, the oxygen getter 140 may be added to the planarization layer 116 under the bank 117.

In addition, in the third embodiment of the present disclosure, the oxygen getter 340 may be additionally disposed in the protective layer 318. For convenience of description, the oxygen getter 140 added to the planarization layer 116 may be referred to as a first oxygen getter 140, and the oxygen getter 340 disposed in the protective layer 318 may be referred to as a second oxygen getter 340.

As described above, according to the third embodiment of the present disclosure, the oxygen permeation may be more effectively blocked through the second oxygen getter 340 disposed in the protective layer 318 formed to cover the first oxygen getter 140 and the outer structure 117′ disposed in the planarization layer 116 under the bank 117.

Meanwhile, according to the present disclosure, an oxygen getter may be added only in the insulating layer under the black bank outside the display area in consideration that cathode damage caused by acidification of the black bank mainly occurs outside the display area, which will be described in detail with reference to the drawings.

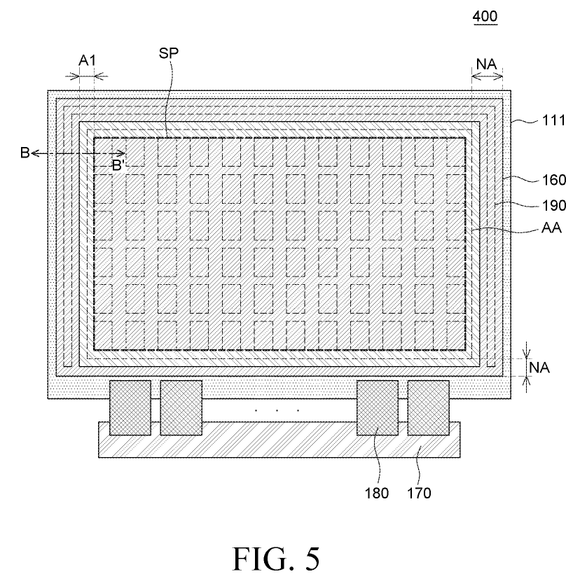

FIG. 5 is a plan view of a display device according to a fourth embodiment of the present disclosure.

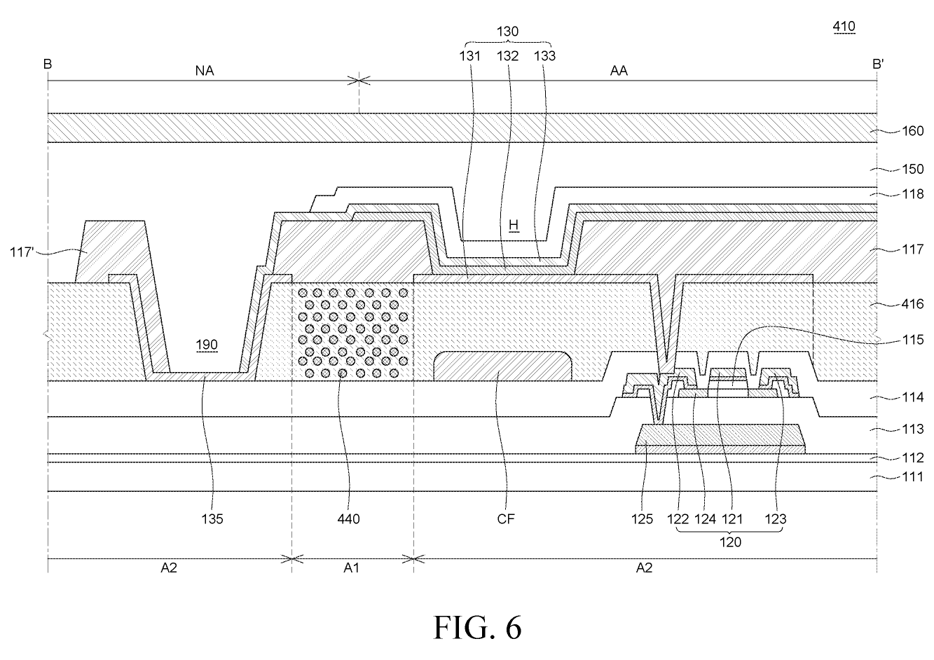

FIG. 6 is a cross-sectional view taken along line B-B' in FIG. 5.

The fourth embodiment shown in FIGS. 5 and 6 is substantially the same as the first embodiment shown in FIGS. 1 and 2 described above except for the arrangement position of the oxygen getter 140. Therefore, repeated descriptions of identical components will be omitted. The same reference numerals will be used for the same elements, and descriptions of the same reference numerals and corresponding elements may be made with reference to FIGS. 1-4.

Referring to FIGS. 5 and 6, the display device 400 according to the fourth embodiment of the present disclosure may include a display panel 410, a flexible film 180, and a printed circuit board 170.

The driving element 120 may be disposed on the substrate 111, and the planarization layer 416 may be disposed on the driving element 120.

The bank 117 may be disposed in an area excluding an emission area on the planarization layer 416.

Like the above-described embodiments, the bank 117 according to the fourth embodiment of the present disclosure may be formed of a black-based resin.

Like the above-described embodiments, a portion of the planarization layer 416 may be removed in the non-display area NA, and the trench pattern 190 may be disposed in the non-display area NA.

For example, the trench pattern 190 may be disposed in the non-display area NA positioned outside the display area AA.

The trench pattern 190 may be disposed in a frame shape along three sides of the non-display area NA excluding one side of the display panel 410. However, the present disclosure is not limited thereto, and for example, the trench pattern 190 may alternatively be disposed in a rectangular frame shape along all four sides of the non-display area NA of the display panel 410.

In addition, the power line 135 may be disposed to cover the inside of the trench pattern 190.

An island-shaped outer structure 117’ covering an outer portion of the power line 135 may be disposed outside the trench pattern 190. In addition, the cathode 133 may extend to the non-display area NA to cover the inner portion of the power line 135. Alternatively, the cathode 133 may cover the inside of the trench pattern 190 and extend to the outer structure 117’, but the present disclosure is not limited thereto.

In addition, the fourth embodiment of the present disclosure is characterized in that the oxygen getter 440 is additionally disposed in the planarization layer 416 under the bank 117. In particular, in the fourth embodiment of the present disclosure, considering that damage to the cathode 133 caused by acidification of the bank 117 mainly occurs at the outer periphery of the display area AA, the oxygen getter 440 may be selectively disposed only in the planarization layer 416 under the bank 117 located at the outer periphery of the display area AA. Accordingly, the permeation of oxygen due to the damage of the cathode 133, which occurs mainly outside the display area AA, may be efficiently prevented, while reducing an amount of the oxygen getter 440 used and improving reliability of the display device 400.

Meanwhile, as described above, the planarization layer 416 may be divided into a first area A1 including an oxygen getter 440 and a second area A2 not including an oxygen getter 440. In FIG. 5, a first area A1 including an oxygen getter 440 is exemplarily illustrated. When the sub pixels SP are disposed in a matrix form, the first area A1 may be set in a rectangular frame shape along an outer periphery of the display area NA while being located inside the trench pattern 190. However, the arrangement shape of the first area A1 is not limited to the rectangular frame shape, and may be modified into various shapes.

Meanwhile, according to the present disclosure, an oxygen getter may be added not only in the planarization layer but also in the bank. Details thereof will be described with reference to the drawings.

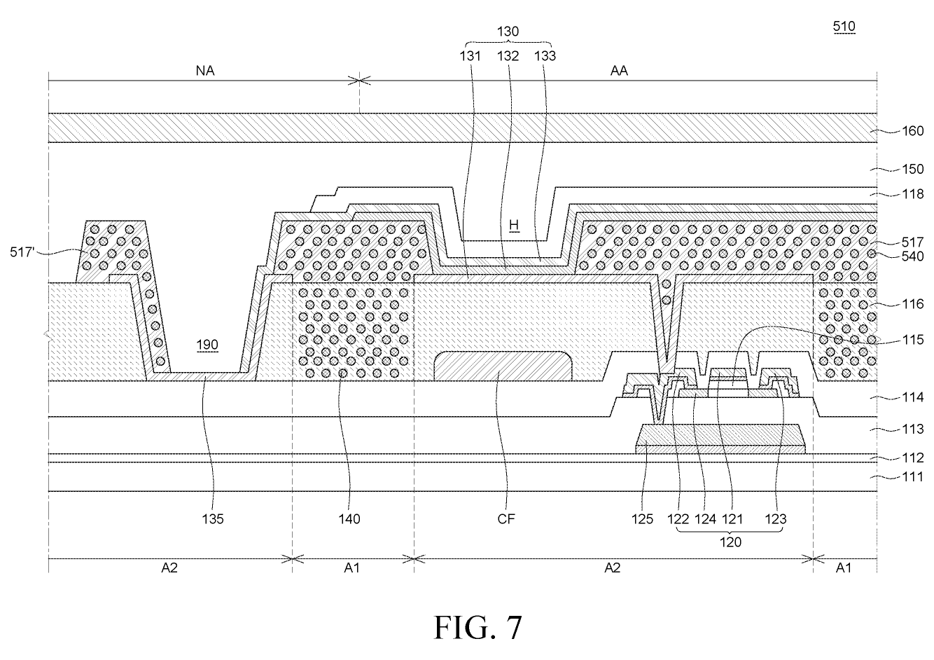

FIG. 7 is a cross-sectional view of a display device according to a fifth embodiment of the present disclosure.

A fifth embodiment of the present disclosure illustrated in FIG. 7 is different from the first embodiment illustrated in FIGS. 1 and 2 described above in that an oxygen getter 540 is added to the bank 517, and other configurations are substantially the same, so that a redundant description will be omitted.

The same reference numerals will be used for the same elements, and descriptions of the same reference numerals and corresponding elements may be made with reference to FIGS. 1-6.

Referring to FIG. 7, in the display panel 510 according to the fifth exemplary embodiment of the present disclosure, the bank 517 may be disposed on the planarization layer 116 in an area excluding an emission area.

The bank 517, according to the fifth embodiment of the present disclosure, may be made of a black-based resin.

Meanwhile, an outer structure 517' having an island shape may be disposed outside the trench pattern 190 to cover an outer portion of the power line 135.

In this case, in the fifth embodiment of the present disclosure, the oxygen getter 540 may be additionally disposed in the bank 517 and the outer structure 517’. The oxygen getter 540 disposed in the bank 517 and the outer structure 517’ may serve to block oxygen permeating through a damaged cathode 133. In particular, the oxygen getter 540 in the bank 517 and the outer structure 517’ may directly absorb and block oxygen penetrating through the damaged cathode 133. Accordingly, dark spot defects due to oxygen permeation may be more effectively prevented, and long-term reliability of the display device may be improved.

Meanwhile, the present disclosure is not limited thereto, and the oxygen getter 540 may be additionally disposed only in the bank 517 or only in the outer structure 517'.

Further, in the fifth embodiment of the present disclosure, the oxygen getter 140 may be added to the planarization layer 116 under the black bank 517. For convenience of description, the oxygen getter 140 added to the planarization layer 116 may be referred to as a first oxygen getter 140, and the oxygen getter 540 disposed in the bank 517 and the outer structure 517’ may be referred to as a second oxygen getter 540.

As described above, according to the fifth embodiment of the present disclosure, the oxygen permeation may be more effectively blocked through the first oxygen getter 140 added in the planarization layer 116 under the bank 517 and the second oxygen getter 540 disposed in the bank 517 and the outer structure 517’. Oxygen introduced from the outside may be transferred to the inside of the display panel 510 through the bank 517 and the planarization layer 116 through the damaged cathode 133. The second oxygen getter 540 may primarily block oxygen permeating through the bank 517 and the outer structure 517’, and the first oxygen getter 140 may secondarily block oxygen permeating through the planarization layer 116. Through this double blocking structure, transmission of oxygen introduced from the outside into the display panel 510 may be effectively suppressed, thereby preventing dark spot defects and deterioration of the light emitting element 130 and improving long-term reliability and lifespan of the display device.

Meanwhile, according to the present disclosure, instead of adding a second oxygen getter in the bank and the outer structure, a getter layer including the second oxygen getter may be deposited on top surfaces of the bank and the outer structure, and more details thereof will be described with reference to the drawings.

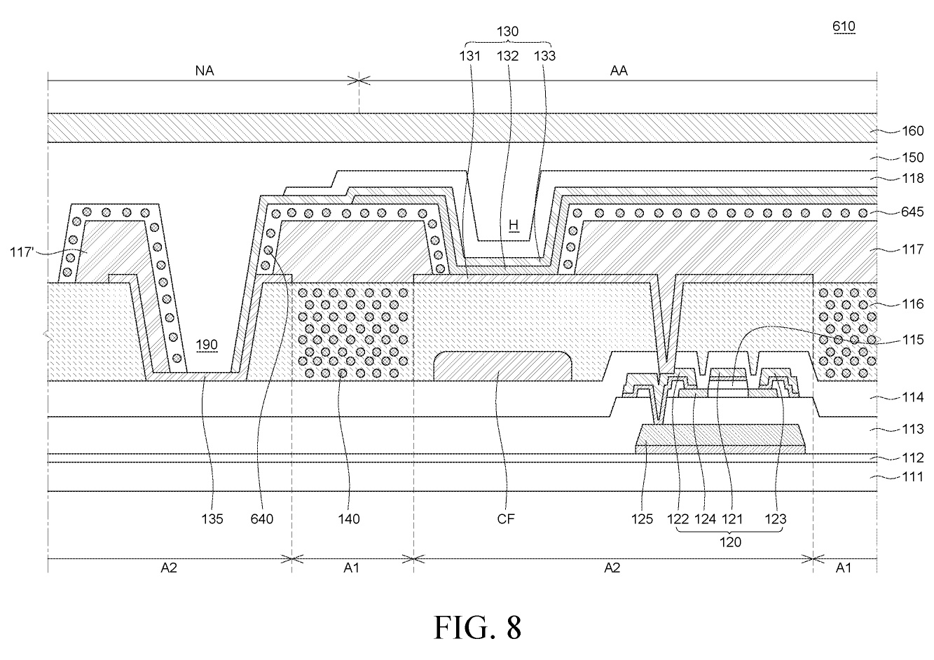

FIG. 8 is a cross-sectional view of a display device according to a sixth embodiment of the present disclosure.

A sixth embodiment of the present disclosure illustrated in FIG. 8 is substantially the same as the first embodiment illustrated in FIGS. 1 and 2 described above except that an oxygen getter 640 is added to top surfaces of the bank 117 and the outer structure 117’. Therefore, a redundant description will be omitted. The same reference numerals will be used for the same elements, and descriptions of the same reference numerals and corresponding elements may be made with reference to FIGS. 1-7.

Referring to FIG. 8, a display panel 610 according to a sixth exemplary embodiment of the present disclosure may include a substrate 111, and a light emitting element 130, a bank 117, and an outer structure 117′ disposed above the substrate 111.

In this case, in the sixth embodiment of the present disclosure, the oxygen getter 140 may be added to the planarization layer 116 under the bank 117. For convenience of description, the oxygen getter 140 added to the planarization layer 116 may be referred to as a first oxygen getter 140.

Further, in the sixth exemplary embodiment of the present disclosure, a getter layer 645 may be additionally disposed on top surfaces of the bank 117 and the outer structure 117′. In this case, the getter layer 645 includes a second oxygen getter 640, and oxygen introduced from the outside may be effectively removed, thereby extending a lifespan of the light emitting element 130.

The getter layer 645 may be formed of an inorganic insulating material.

For example, the getter layer 645 may be deposited using a physical vapor deposition method (PVD), a chemical vapor deposition method (CVD), or an atomic layer deposition method (ALD), and may include a metal having high reactivity with oxygen or a compound having an excellent oxygen trapping function. Further, for example, the second oxygen getter 640 may include cerium dioxide (CeO2), a barium-calcium (BaCa)-based metal oxide, a carbon molecular sieve or an alkaline earth metal such as barium (Ba), magnesium (Mg), strontium (Sr), and beryllium (Be). However, the present disclosure is not limited thereto.

For example, the getter layer 645 may be disposed to surround upper and side surfaces of the bank 117 and the outer structure 117’, but the present disclosure is not limited thereto. The getter layer 645 may be disposed only on top surfaces of the bank 117 and the outer structure 117’.

In the case of the sixth configuration of the present disclosure, the organic layer 132 may be disposed on the side and top surfaces of the getter layer 645. The cathode 133 may be disposed on the organic layer 132. In addition, the cathode 133 may extend into the trench pattern 190 to cover the inner portion of the exposed power line 135 and upper and side surfaces of the getter layer 645, but the present disclosure is not limited thereto.

As described above, according to the sixth embodiment of the present disclosure, the oxygen permeation may be more effectively blocked through the first oxygen getter 140 added to the planarization layer 116 under the bank 117 and the getter layer 645 disposed on the top surfaces of the bank 117 and the outer structure 117’. Through this double blocking structure, it is possible to effectively suppress the transmission of oxygen introduced from the outside to the inside of the display panel 610, thereby preventing a dark spot defect and deterioration of the light emitting element 130 and improving long-term reliability and lifespan of the display device.

Further, in the sixth exemplary embodiment of the present disclosure, an oxygen removal function may be performed by using a getter layer 645 disposed on the top surface without including a separate oxygen getter in the bank 117 and the outer structure 117’. This configuration simplifies a manufacturing process and allows more flexible adjustment of an arrangement of oxygen getter materials.

Further, in the sixth embodiment of the present disclosure, the oxygen removal performance may be adjusted by adjusting the deposition thickness of the getter layer 645, and an oxygen removal effect may be further enhanced by forming the getter layer 645 in a multilayer structure as needed.

Meanwhile, according to the present disclosure, an oxygen getter is added in the planarization layer over an entire area, and an amount of oxygen getter added to each area may be adjusted. Details thereof will be described with reference to the accompanying drawings.

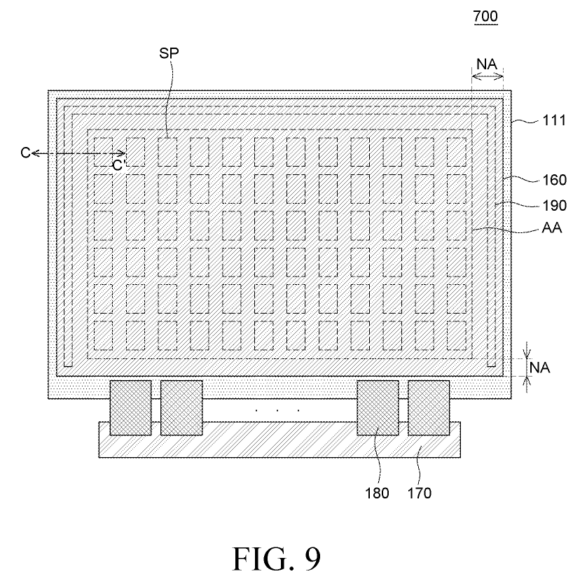

FIG. 9 is a plan view of a display device according to a seventh embodiment of the present disclosure.

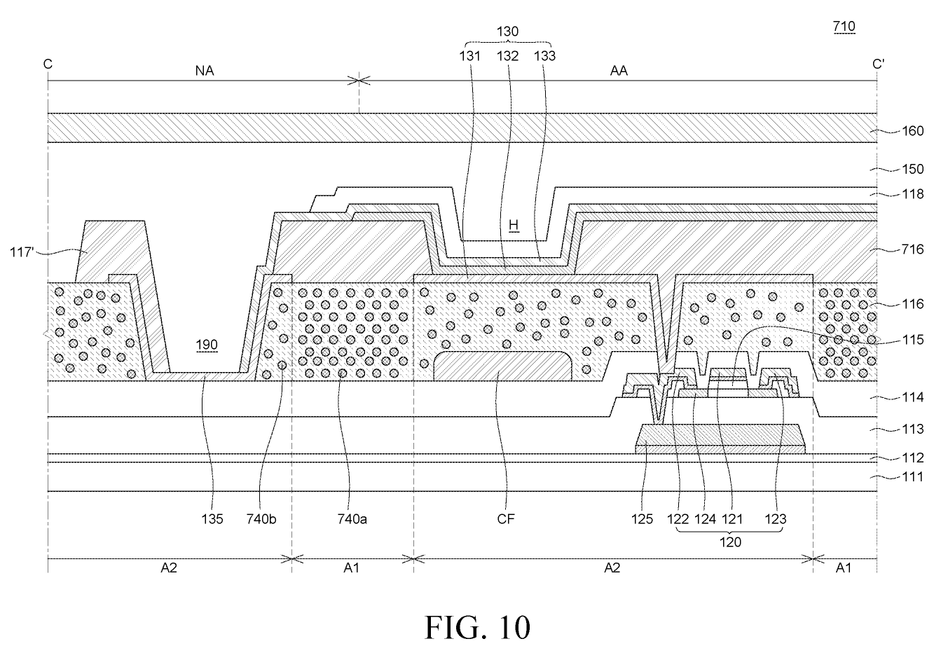

FIG. 10 is a cross-sectional view taken along line C-C' in FIG. 9.

The seventh embodiment of the present disclosure illustrated in FIGS. 9 and 10 is substantially the same as the first embodiment illustrated in FIGS. 1 and 2 described above except that amounts of oxygen getters 740a and 740b added to a first area A1 and a second area A2 of a planarization layer 716 are different. Therefore, a redundant description will be omitted. The same reference numerals are used for the same elements, and descriptions of the same reference numerals and corresponding elements may be made with reference to FIGS. 1-8.

Referring to FIGS. 9 and 10, the display device 700 according to the seventh exemplary embodiment of the present disclosure may include a display panel 710, a flexible film 180, and a printed circuit board 170.

The driving element 120 may be disposed on the substrate 111.

In addition, a planarization layer 716 may be disposed on the driving element 120.

For example, the planarization layer 716 may extend to the end of the substrate 111 in the non-display area NA, but the present disclosure is not limited thereto and the planarization layer 716 may be disposed to be spaced apart from the end of the substrate 111 by a predetermined distance.

The bank 117 may be disposed in the remaining area excluding the emission area on the planarization layer 716.

Like the above-described embodiments, the bank 117 according to the seventh embodiment of the present disclosure may be formed of a black-based resin. Further, according to the seventh exemplary embodiment of the present disclosure, a part of the planarization layer 716 may be removed from the non-display area NA, and the trench pattern 190 may be disposed in the non-display area NA. Further, an island-shaped outer structure 117’ may be disposed outside the trench pattern 190 to cover an outer portion of the power line 135.

Meanwhile, the seventh embodiment of the present disclosure is characterized in that oxygen getters 740a and 740b are added to the planarization layer 716 under the bank 117 and the outer structure 117’.

In this case, the planarization layer 716 according to the seventh exemplary embodiment of the present disclosure may be divided into a first area A1 and a second area A2.

For example, the second area A2 may correspond to an emission area in which the light emitting element 130 is disposed and a circuit area in which a circuit such as the thin film transistor TFT is disposed.

In addition, the first area A1 may correspond to a display area AA excluding the emission area and the circuit area, and a non-display area NA excluding the trench pattern 190.

In this case, the first oxygen getter 740a may be disposed in the first area A1 of the planarization layer 716, and the second oxygen getter 740b may be disposed in the second area A2 of the planarization layer 716.

The first oxygen getter 740a disposed in the first area A1 may be disposed at a higher density than the second oxygen getter 740b disposed in the second area A2, but the present disclosure is not limited thereto.

The first oxygen getter 740a disposed in the first area A1 may be disposed in a larger amount than the second oxygen getter 740b disposed in the second area A2.

The seventh embodiment of the present disclosure provides a structure in which oxygen getters 740a and 740b are added in the planarization layer 716 of the entire area, while amounts of oxygen getters 740a and 740b added to the first area A1 and the second area A2 are differently adjusted. Thus, oxygen permeation can be blocked more effectively, and the arrangement of the oxygen getter may be flexibly adjusted according to the requirements of each area. That is, locations and amounts at which the oxygen getters added to respective areas may be set to optimize performance of the display device. The planarization layer may be divided into several areas, and the amount of oxygen getter added to each area may be adjusted differently for each area. For example, a relatively larger amount of oxygen getter may be disposed in an area in which oxygen permeation is of greater concern, and a smaller amount of oxygen getter may be disposed in an area in which oxygen permeation of lesser concern, thereby achieving efficient oxygen blocking.

The exemplary embodiments of the present disclosure can also be described as follows:

A display device according to an exemplary embodiment of the present disclosure may include a substrate including a display area and a non-display area, a planarization layer disposed over the substrate and extending from the display area to the non-display area, an anode disposed on the planarization layer, a bank disposed on the planarization layer and exposing a part of the anode corresponding to an emission area, and extending to the non-display area, an organic layer disposed in the emission area, an organic layer disposed on the organic layer and extending to the non-display area, a protective layer disposed on the cathode, and an oxygen getter disposed in the planarization layer under the bank.

According to another aspect of the present disclosure, the display device may further include at least one trench pattern disposed in the non-display area and configured by removing the planarization layer.

According to yet another aspect of the present disclosure, the display device may further include a power line disposed to cover the inside of the trench pattern.

According to yet another aspect of the present disclosure, the power line may be disposed to cover a side surface of the planarization layer exposed by the trench pattern.

According to yet another aspect of the present disclosure, the cathode may extend in the trench pattern to cover an inner portion of the power line.

According to yet another aspect of the present disclosure, the display device may further include an outer structure disposed outside the trench pattern in an island shape to cover an outer portion of the power line.

According to yet another aspect of the present disclosure, the bank and the outer structure may be made of a black-based resin.

According to yet another aspect of the present disclosure, the oxygen getter may be disposed in a partial area of the planarization layer that does not include the anode on an upper surface thereof.

According to yet another aspect of the present disclosure, the oxygen getter may be disposed in a first area of the planarization layer and may not be disposed in a second area other than the first area.

According to yet another aspect of the present disclosure, the first area may correspond to a part of the display area corresponding to a boundary between sub pixels and a part of the non-display area located inside the trench pattern.

According to yet another aspect of the present disclosure, the second area may correspond to a circuit area in which the emission area and a circuit of a thin film transistor are disposed, and the first area may correspond to a part of the display area excluding the emission area and the circuit area and a part of the non-display area excluding the trench pattern.

According to yet another aspect of the present disclosure, the oxygen getter may include cerium dioxide (CeO2), a barium-calcium (BaCa)-based metal oxide, a carbon molecular sieve or an alkaline earth metal of barium (Ba), magnesium (Mg), strontium (Sr), and beryllium (Be).

According to yet another aspect of the present disclosure, the protective layer may be made of an inorganic insulating material, and the protective layer may extend into the trench pattern to cover the cathode.

According to yet another aspect of the present disclosure, the cathode may be disposed to extend into the trench pattern and further to the outer structure, and the protective layer may be disposed to cover the outer structure including the cathode.

According to yet another aspect of the present disclosure, the display device may further include another oxygen getter disposed in the protective layer.

According to yet another aspect of the present disclosure, the oxygen getter may be disposed only in the planarization layer under the bank located outside the display area.

According to yet another aspect of the present disclosure, the display device may further include another oxygen getter disposed in the bank.

According to yet another aspect of the present disclosure, the display device may further include a getter layer disposed to enclose an upper portion and a side portion of the bank, and the getter layer may include another oxygen getter.

According to yet another aspect of the present disclosure, the oxygen getter may include a first oxygen getter disposed in a first area of the planarization layer and a second oxygen getter disposed in a second area of the planarization layer, and the first oxygen getter may be disposed at a higher density than the second oxygen getter.

According to yet another aspect of the present disclosure, the second area may correspond to a circuit area in which the emission area and a circuit of a thin film transistor are disposed, and the first area may correspond to a part of the display area excluding the emission area and the circuit area and a part of the non-display area excluding the trench pattern.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area and a non-display area;
a planarization layer disposed over the substrate and extending from the display area to the non-display area;
an anode disposed on the planarization layer;
a bank disposed on the planarization layer, exposing a portion of the anode corresponding to an emission area and extending to the non-display area;
an organic layer disposed in the emission area;
a cathode disposed on the organic layer and extending to the non-display area;
a protective layer disposed on the cathode; and
an oxygen getter disposed in the planarization layer under the bank.

2. The display device according to claim 1, further comprising:
at least one trench pattern disposed in the non-display area and configured by removing the planarization layer.

3. The display device according to claim 2, further comprising:
a power line disposed to cover an inside of a trench pattern of the at least one trench pattern.

4. The display device according to claim 3, wherein the power line is disposed to cover a side surface of the planarization layer exposed by the trench pattern.

5. The display device according to claim 3, wherein the cathode extends into the trench pattern to cover an inner portion of the power line.

6. The display device according to claim 3, further comprising:
an outer structure disposed on outside the trench pattern in an island shape to cover an outer portion of the power line.

7. The display device according to claim 6, wherein the bank and the outer structure are made of a black-based resin.

8. The display device according to claim 1, wherein the oxygen getter is disposed in a partial area of the planarization layer that does not include the anode on an upper surface thereof.

9. The display device according to claim 1, wherein the oxygen getter is disposed in a first area of the planarization layer and is not disposed in a second area other than the first area.

10. The display device according to claim 9, wherein the first area corresponds to a part of the display area corresponding to a boundary between sub pixels and a part of the non-display area located inside a trench pattern disposed in the non-display area.

11. The display device according to claim 9, wherein the second area corresponds to a circuit area in which the emission area and a circuit of a thin film transistor are disposed, and
wherein the first area corresponds to a part of the display area excluding the emission area and the circuit area and a part of the non-display area excluding the trench pattern.

12. The display device according to claim 1, wherein the oxygen getter includes cerium dioxide (CeO2), a barium-calcium (BaCa)-based metal oxide, a carbon molecular sieve or an alkaline earth metal of barium (Ba), magnesium (Mg), strontium (Sr), and beryllium (Be).

13. The display device according to claim 1, wherein the protective layer is made of an inorganic insulating material, and
wherein the protective layer extends into a trench pattern to cover the cathode, the trench pattern disposed in the non-display area.

14. The display device according to claim 6, wherein the cathode is disposed to extend into the trench pattern and further to the outer structure, and
wherein the protective layer includes the cathode and is disposed to cover the outer structure.

15. The display device according to claim 1, further comprising:
another oxygen getter disposed in the protective layer.

16. The display device according to claim 1, wherein the oxygen getter is disposed only in the planarization layer under the bank located outside the display area.

17. The display device according to claim 1, further comprising:
another oxygen getter disposed in the bank.

18. The display device according to claim 1, further comprising:
a getter layer disposed to enclose an upper portion and a side portion of the bank,
wherein the getter layer comprises another oxygen getter.

19. The display device according to claim 1, wherein the oxygen getter includes a first oxygen getter disposed in a first area of the planarization layer and a second oxygen getter disposed in a second area of the planarization layer, and
wherein the first oxygen getter is disposed at a higher density than the second oxygen getter.

20. The display device according to claim 19, wherein the second area corresponds to a circuit area in which the emission area and a circuit of a thin film transistor are disposed, and
wherein the first area corresponds to a part of the display area excluding the emission area and the circuit area and a part of the non-display area excluding a trench pattern disposed in the non-display area.
